(19) United States
(12) Patent Application Publication
(10) Pub. No.: US 2018/0151364 A1
(43) Pub. Date: May 31, 2018

(54) METHOD OF MANUFACTURING SEMICONDUCTOR DEVICE

(71) Applicant: TOYOTA JIDOSHA KABUSHIKI KAISHA, Toyota-shi (JP)

(72) Inventors: Hiroyuki YOSHIDA, Toyota-shi (JP); Ippei TAKAHASHI, Nagakute-shi (JP); Yasushi URAKAMI, Kariya-shi (JP)

(73) Assignee: TOYOTA JIDOSHA KABUSHIKI KAISHA, Toyota-shi (JP)

(21) Appl. No.: 15/789,273

(22) Filed: Oct. 20, 2017

(30) Foreign Application Priority Data
Nov. 28, 2016 (JP) 2016-230502

(51) Int. Cl. H01L 21/04; H01L 29/45; H01L 29/16; H01L 21/304; H01L 29/66

(52) U.S. Cl. CPC H01L 21/043; H01L 21/042; H01L 29/45; H01L 29/66143; H01L 21/304; H01L 29/6606; H01L 29/1608

(57) ABSTRACT

A method of manufacturing a semiconductor device is provided. The method includes: grinding a surface of an SiC wafer so that a crushed layer having a thickness of 5 nm or more is formed in a range exposed on the surface; forming a metal layer covering the crushed layer; and making the metal layer and the crushed layer react with each other by heating so as to form a silicide layer in ohmic contact with the SiC wafer. At least a part of the crushed layer covered with the metal layer transforms to the silicide layer over its entire depth.

### TECHNICAL FIELD

The technique disclosed herein relates to a method of manufacturing a semiconductor device.

### BACKGROUND

A method of manufacturing a semiconductor device is disclosed in International Publication No. WO 2012/049792. This manufacturing method includes grinding, removing a crushed layer, forming a metal layer and forming a silicide layer. In the grinding, a surface of a SiC wafer is ground. While grinding the surface of the SiC wafer, crystal defects are formed in a semiconductor layer near the surface of the SiC wafer. Hereinafter, a semiconductor layer in which a crystal defect density has been increased due to grinding, will be referred to as a crushed layer. In International Publication No. WO 2012/049792, the crushed layer is referred to as an affected layer. In the removing of the crushed layer, the crushed layer is removed by RIE (Reactive Ion Etching), sputtering, wet etching, dry etching, dry polishing, CMP (Chemical Mechanical Polishing) or the like. In the forming of the metal layer, the metal layer is formed on the surface of the SiC wafer from which the crushed layer has been removed. In the forming of the silicide layer, the silicide layer in ohmic contact with the SiC wafer is formed by reacting the metal layer and the SiC wafer by heating. According to this manufacturing method, contact resistance between the silicide layer and the SiC wafer can be reduced.

### SUMMARY

In the manufacturing method of International Publication No. WO 2012/049792, the forming of the metal layer and the forming of the silicide layer are carried out after the removing of the crushed layer, thereby reducing the contact resistance of the silicide layer to the SiC wafer. However, in this manufacturing method, since it is necessary to remove the crushed layer, there is a problem that a large number of steps is required for forming the silicide layer. The present disclosure provides a technique capable of more efficiently forming a silicide layer having low contact resistance to a SiC wafer.

A method of manufacturing a semiconductor device disclosed herein comprises grinding, forming a metal layer, and forming a silicide layer. In the grinding, a surface of an SiC wafer is ground. In the grinding, a crushed layer having a thickness of 5 nm or more is formed in a range exposed on the surface. In the forming of the metal layer, the metal layer covering the crushed layer is formed. In the forming of the silicide layer, the metal layer and the crushed layer are made to react with each other by heating so as to form the silicide layer in ohmic contact with the SiC wafer. In the forming of the silicide layer, at least a part of the crushed layer covered with the metal layer transforms to the silicide layer over its entire depth.

It should be noted that the above-mentioned crushed layer refers to a semiconductor layer that is included in the SiC wafer and has an increased crystal defect density due to the grinding. The crushed layer is formed in the range exposed on a ground surface of the SiC wafer.

Further, the above-mentioned grinding refers to a step of grinding the surface of the semiconductor water, by which a crushed layer having a thickness of 5 nm or more is formed. For example, a step of mechanically grinding the surface of the semiconductor wafer with abrasive grains or the like is one type of the grinding. In addition, there is a grinding step in which crushed layer is hardly generated, such as CMP. Since the thickness of the crushed layer is less than 5 nm in this type of grinding, it is not encompassed in the grinding herein referred to.

Further, the above-mentioned silicide layer refers to a layer including the silicide layer that has been generated as a result of reaction between the metal layer and the crushed later.

In the above-described manufacturing method, the metal layer is formed on the surface of the crushed layer without removing the crushed layer after the grinding. Then, by making the metal layer and the crushed layer react with each other by heating, the silicide layer in ohmic contact with the SiC wafer is formed. In this case, by adjusting heating conditions (heating temperature, heating time, etc.), at least a part of the crushed layer in a range covered with the metal layer is transformed to the silicide layer over its entire depth. Due to this, in at least a part of the range, the crushed layer does not exist at an interface between the silicide layer and the SiC wafer, and the contact resistance of the silicide layer to the SiC wafer is reduced. As described above, according to this manufacturing method, it is possible to efficiently form the silicide layer having low contact resistance to the SiC wafer without carrying out the step of removing the crushed layer before the step of forming the metal layer.

### BRIEF DESCRIPTION OF DRAWINGS

FIG. 1 is a cross sectional view of an SBD 10.

FIG. 2 is an enlarged cross-sectional view of an ohmic electrode 30.

FIG. 3 is an explanatory diagram of a manufacturing process of the SBD10.

FIG. 4 is an explanatory diagram of the manufacturing process of the SBD10.

FIG. 5 is an explanatory diagram of the manufacturing process of the SBD10.

### DETAILED DESCRIPTION

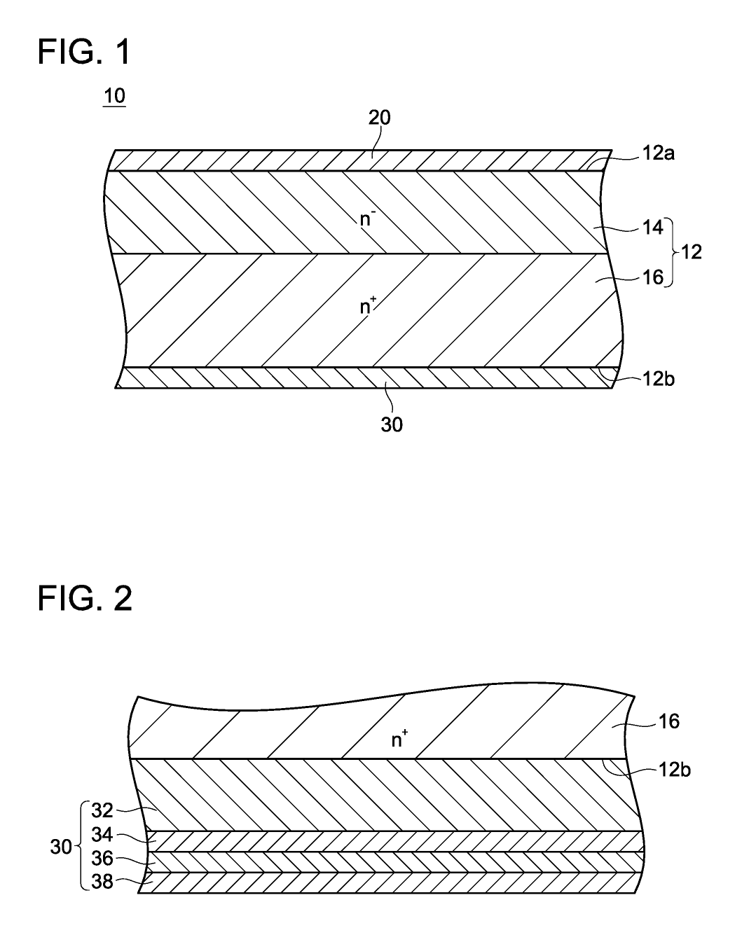

FIG. 1 shows a Schottky barrier diode 10 (hereinafter referred to as an SBD 10) manufactured by a manufacturing method of an embodiment. The SBD 10 comprises an SiC substrate 12, a Schottky electrode 20, and an ohmic electrode 30. The SiC substrate 12 is a semiconductor substrate mainly constituted of SiC (silicon carbide). The SiC substrate 12 has an n-type low concentration layer 14 and an n-type high concentration layer 16. The n-type low concentration layer 14 is provided on an upper surface 12a side of the SiC substrate 12. The n-type high concentration layer 16 is provided on a lower surface 12b side of the SiC substrate 12. The Schottky electrode 20 is disposed on an upper surface 12a of the SiC substrate 12 and is in Schottky contact with the n-type low concentration layer 14. The ohmic electrode 30 is disposed on the lower surface 12b of the SiC substrate 12 and is in ohmic contact with the n-type high-concentration layer 16.

FIG. 2 shows a detailed structure of the ohmic electrode 30. As shown in FIG. 2, the ohmic electrode 30 comprises a silicide layer 32, a titanium layer 34, a nickel layer 36, and a gold layer 38. The silicide layer 32 is a layer mainly constituted of an alloy of nickel silicide (NiSi) and molybdenum carbide (MoC). The silicide layer 32 is provided on the lower surface 12b of the SiC substrate 12 and is in ohmic contact with the n-type high concentration layer 16. The titanium layer 34 is a layer mainly constituted of titanium (Ti). The titanium layer 34 is in contact with a lower surface of the silicide layer 32. The nickel layer 36 is a layer mainly constituted of nickel (Ni). The nickel layer 36 is in contact with a lower surface of the titanium layer 34. The gold layer 38 is a layer mainly constituted of gold (Au). The gold layer 38 is in contact with a lower surface of the nickel layer 36.

A manufacturing method of the SBD 10 will be described. First, an SiC wafer 12 (a wafer corresponding to the above-described SiC substrate 12) comprising an n-type low concentration layer 14 and an n-type high concentration layer 16 is prepared. Next, a Schottky electrode 20, other semiconductor layers, insulating layers, electrodes and the like (not shown) are formed on an upper surface 12a side of the SiC wafer 12.

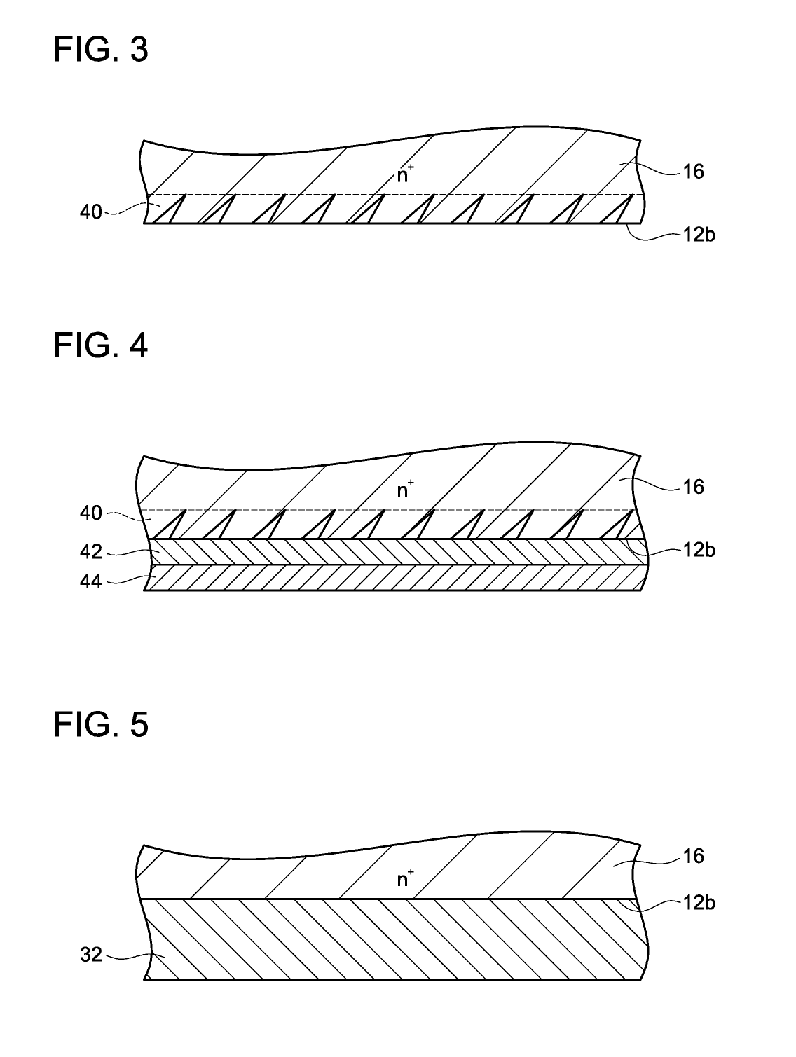

Next, the SiC wafer 12 is thinned by grinding a lower surface 12b (a surface on which the n-type high concentration layer 16 is exposed) of the SiC wafer 12. As shown in FIG. 3, the lower surface 12b of the SiC wafer 12 is ground such that the n-type high concentration layer 16 remains. A crushed layer 40 is formed in the semiconductor layer (part of the n-type high concentration layer 16) in a range exposed on the lower surface 12b of the SiC wafer 12 by grinding. The crushed layer 40 is a semiconductor layer in which crystal defect density is increased due to the grinding. Here, the crushed layer 40 having a thickness of 5 nm or more is formed. In many cases, the crushed layer 40 formed in the grinding has the thickness of 50 nm or more. Further, the thickness of the crushed layer 40 may be 500 nm or less.

Next, as shown in FIG. 4, a molybdenum layer 42 covering the lower surface 12b of the SiC wafer 12 (that is, a surface of the crushed layer 40) is formed. The molybdenum layer 42 is a metal layer mainly constituted of molybdenum (Mo). Further, a nickel layer 44 covering a lower surface of the molybdenum layer 42 is formed. The nickel layer 44 is a metal layer mainly constituted of nickel (Ni).

Next, the nickel layer 44, the molybdenum layer 42, and the n-type high concentration layer 16 are heated by radiating laser onto a lower surface of the nickel layer 44. By heating, materials diffuse mutually between the nickel layer 44, the molybdenum layer 42, and the n-type high concentration layer 16. In particular, since the crystal defect density of the crushed layer 40 is high, diffusion of nickel and molybdenum into the crushed layer 40 is promoted. Nickel in the nickel layer 44 reacts with silicon (Si) in the n-type high concentration layer 16 (i.e., SiC layer) to form nickel silicide (NiSi). In addition, molybdenum in the molybdenum layer 42 reacts with carbon (C) in the n-type high concentration layer 16 to form molybdenum carbide (MoC). As a result, as shown in FIG. 5, a silicide layer 32 constituted of an alloy of nickel silicide and molybdenum carbide is formed. The silicide layer 32 makes an ohmic contact with the n-type high concentration layer 16 (i.e., the SiC wafer 12). Here, by adjusting heating temperature and heating time, the crushed layer 40 is transformed to the silicide layer 32 over its entire depth. Due to this, the crushed layer 40 is eliminated. For example, when the crushed layer 40 has a thickness of 225 nm or less, the crushed layer 40 can be transformed to the silicide layer 32 over its entire depth by heating the crushed layer 40 at a temperature of 1200° C. or more for 150 nsec or more. Since the crushed layer 40 is transformed to the silicide layer 32 over its entire depth, the formed silicide layer 32 is brought into contact with the n-type high concentration layer 16 (the n-type high concentration layer 16 having a low crystal defect density), which is not the crushed layer 40. Since the crushed layer 40 does not exist at an interface between the silicide layer 32 and the n-type high concentration layer 16, contact resistance of the silicide layer 32 to the n-type high concentration layer 16 is small.

Next, as shown in FIG. 2, a titanium layer 34, a nickel layer 36, and a gold layer 38 are laminated on a lower surface of the silicide layer 32. Then, a plurality of the SBDs 10 is finished by dicing the SiC wafer 12.

As explained above, according to the manufacturing method disclosed herein, the silicide layer 32 that is in ohmic contact with the SiC wafer 12 at low resistance can be formed without removing the crushed layer 40 before forming the molybdenum layer 42 and the nickel layer 44. Since a step of removing the crushed layer 40 is not carried out, a number of steps required for forming the silicide layer 32 can be reduced. Therefore, according to this manufacturing method, the SBD 10 can be efficiently manufactured.

Further, if the step of removing the crushed layer is carried out as in the above-described International Publication No. WO 2012/049792, there is a case that the SiC wafer is damaged during the step of removing the crushed layer. In contrast, in the technique disclosed herein, since the crush layer 40 is not removed, damage to the SiC wafer 12 can be reduced. Therefore, chipping or the like of the SiC wafer 12 can be suppressed.

Further, in the manufacturing method disclosed herein, since heat treatment for silicidation is carried out in the presence of the crushed layer 40, silicidation reaction between the nickel layer 44, the molybdenum layer 42, and the n-type high concentration layer 16 is enhanced. Due to this, throughput of the heat treatment process is improved, and the SBD 10 can be manufactured more efficiently.

It should be noted that the crush layer 40 may be transformed to the silicide layer 32 only in a part of the lower surface 12b over its entire depth. According to this configuration as well, the contact resistance of the silicide layer 32 can be reduced.

It should be noted that although the method for manufacturing the SBD 10 is described in the above-described embodiment, the manufacturing method disclosed herein can be applied to other semiconductor devices having an electrode in ohmic contact with the SiC wafer.

While specific examples of the present invention have been described above in detail, these examples are merely illustrative and place no limitation on the scope of the patent claims. The technology described in the patent claims also encompasses various changes and modifications to the specific examples described above. The technical elements explained in the present description or drawings provide technical utility either independently or through various combinations. The present invention is not limited to the combinations described at the time the claims are filed. Further, the purpose of the examples illustrated by the present description or drawings is to satisfy multiple objectives simultaneously, and satisfying any one of those objectives gives technical utility to the present invention.

What is claimed is:

1. A method of manufacturing a semiconductor device, the method comprising:
grinding a surface of an SiC wafer so that a crushed layer having a thickness of 5 nm or more is formed in a range exposed on the surface;
forming a metal layer covering the crushed layer; and
making the metal layer and the crushed layer react with each other by heating so as to form a silicide layer in ohmic contact with the SiC wafer, wherein at least a part of the crushed layer covered with the metal layer transforms to the silicide layer over an entire depth of the crushed layer.
